(19) United States
(12) Patent Application Publication
(10) Pub. No.: US 2024/0120235 A1
(43) Pub. Date: Apr. 11, 2024

(54) Magnetically Opposed, Iron Core Linear Motor Based Motion Stages For Semiconductor Wafer Positioning

(71) Applicant: KLA Corporation, Milpitas, CA (US)

(72) Inventors: Michel Pharand, Los Gatos, CA (US); Stephen Doll, Berkeley, CA (US); Samir Nayfeh, Dunn Loring, VA (US)

(21) Appl. No.: 18/375,920

(22) Filed: Oct. 2, 2023

Related U.S. Application Data
(60) Provisional application No. 63/413,250, filed on Oct. 5, 2022.

(51) Int. Cl. H01L 21/687; H02K 3/47; H02K 7/09; H02K 41/03

(52) U.S. Cl. CPC H01L 21/68764; H02K 3/47; H02K 7/09; H02K 41/031

(57) ABSTRACT

Methods and systems for realizing a high throughput wafer positioning system with high positioning accuracy are presented herein. The high throughput, high accuracy wafer positioning system is employed to measure structural and material characteristics (e.g., material composition, dimensional characteristics of structures and films, etc.) associated with different semiconductor fabrication processes. In one aspect, iron core linear motor assemblies are arranged in a magnetically opposed configuration such that the magnetic attraction forces inherent to each opposing iron core linear motor assembly largely cancel one another. The reduced force applied to sensitive stage frame elements, in turn, reduces induced deformations and stage positioning errors. In some embodiments, a wafer positioning system includes stacked magnetically opposed long stroke stages. In some of these embodiments, both magnetically opposed long stroke stages employ magnet tracks mechanically coupled to the intermediate frame of the stacked stage assembly.

### CROSS REFERENCE TO RELATED APPLICATION

The present application for patent claims priority under 35 U.S.C. § 119 from U.S. provisional patent application Ser. No. 63/413,250, entitled “Stacked XY Stage with moving magnets for high thermal stability,” filed Oct. 5, 2022, the subject matter of which is incorporated herein by reference in its entirety.

### TECHNICAL FIELD

The described embodiments relate to wafer positioning systems and methods, and more particularly to methods and systems for improved high throughput positioning of wafers in a manufacturing environment.

### BACKGROUND INFORMATION

The various features and multiple structural levels of semiconductor devices such as logic and memory devices are typically fabricated by a sequence of processing steps applied to a specimen. For example, lithography among others is one semiconductor fabrication process that involves generating a pattern on a semiconductor wafer. Additional examples of semiconductor fabrication processes include, but are not limited to, chemical-mechanical polishing, etch, deposition, and ion implantation. Multiple semiconductor devices may be fabricated on a single semiconductor wafer and then separated into individual semiconductor devices.

Metrology processes are used at various steps during a semiconductor manufacturing process to detect defects on wafers to promote higher yield. Optical metrology techniques offer the potential for high throughput without the risk of sample destruction. A number of optical metrology based techniques including scatterometry, reflectometry, and ellipsometry implementations and associated analysis algorithms are commonly used to characterize critical dimensions, film thicknesses, composition and other parameters of nanoscale structures.

As devices (e.g., logic and memory devices) move toward smaller nanometer-scale dimensions, characterization becomes more difficult. Devices incorporating complex three-dimensional geometry and materials with diverse physical properties contribute to characterization difficulty. In response, more complex optical tools have been developed. For example, tools with multiple angles of illumination, shorter and broader ranges of illumination wavelengths, and more complete information acquisition from reflected signals (e.g., measuring multiple Mueller matrix elements in addition to the more conventional reflectivity or ellipsometric signals) have been developed.

As devices move toward smaller nanometer-scale dimensions, commercially viable optically based measurement tools must position samples faster and with greater accuracy. Typically, a wafer position system must move a semiconductor wafer over a long distance in two dimensions, typically referred to as the X and Y directions. To quickly move over long distances and accurately locate a wafer under measurement in a short amount of time requires a large amount of driving force. These forces are typically generated by linear electric motors. However, linear motors capable of generating large forces generate a significant amount of heat. Available wafer positioning systems suffer from significant limitations on achievable positioning accuracy due to thermal distortions induced by the heat generated by the linear motors.

Available wafer positioning systems typically employ low thermal conductivity materials in an attempt to thermally isolate sensitive stage frame elements from the heat generated by the linear motors. Unfortunately, it is common to observe temperature increases of at least one degree Centigrade across sensitive stage frame elements. These temperature changes induce significant deformations across sensitive stage frame elements, causing degradation of accuracy. In addition, sensitive stage frame elements often include different materials having significantly different coefficients of thermal expansion (CTE). The mismatched CTEs, along with the change in temperature, induce significant internal strain and associated deformations within the sensitive stage frame elements, which further degrades stage positioning accuracy.

FIG. 1 is a simplified diagram illustrative of a typical prior art wafer positioning system 10 in one embodiment. Wafer positioning system 10 includes a stage base frame 11 and an intermediate frame 12. Coordinate frame {X_{IF}, Y_{IF}, Z_{IF}} is fixed to intermediate frame 12. A set of mechanical linear bearings 13 constrain the relative motion of intermediate frame 12 with respect to stage base frame 11 to one degree of freedom, i.e., the Y_{IF}-direction. FIG. 1 also illustrates an ironless, U-channel linear motor including a U-channel magnet track 14 and an ironless motor assembly 15. As depicted in FIG. 1, the ironless motor assembly 15 is mechanically fixed to the intermediate frame 12 and the U-channel magnet track 14 is mechanically fixed to the stage base frame 11. The ironless motor assembly 15 includes multiple electrically conductive wire coils embedded in a non-magnetic package. In some examples, the copper coils are embedded in an epoxy matrix material that fills an aluminum or copper housing. The U-channel magnet track 14 includes multiple permanent magnets attached to magnetic backing plates on both sides of the U-shaped channel. This assembly generates a well-defined magnetic field across the U-shaped channel. As depicted in FIG. 1, magnetic field lines 17 are concentrated in the permanent magnets and ferrous backing plates of the U-shaped magnet track. The portion of the magnetic field external to the U-shaped magnet track is limited to the relatively small gap across the U-shaped channel.

As depicted in FIG. 1, the ironless motor assembly 15 is disposed within the U-shaped channel. A mechanical driving force is generated in the Y-direction by flowing electrical current through the windings of the coils of the ironless motor assembly 15. The orientation of the coil windings relative to the magnetic field across the U-shaped channel is such that the interaction of the current flow with the magnetic field generates a mechanical driving force in the Y-direction.

An ironless, U-channel linear motor is an inherently smooth operating motor due to the lack of iron in the ironless motor assembly 15. There are no significant magnetic attraction forces generated between the ironless motor assembly 15 and U-channel magnet track 14. As such, the ironless motor assembly 15 is able to operate within the U-channel at any relative position with respect to the permanent magnets of the magnet track 14 without creating substantial off-axis forces. In addition, the magnetic field generated across the U-channel is relatively undisturbed by the ironless motor assembly 15. Thus, the position dependence of the driving force generated between the ironless motor assembly 15 and U-channel magnet track 14 is relatively smooth and predictable. As such, a relatively simple control algorithm can be employed to distribute current through the coils of ironless motor assembly 15 such that the driving force generated between the ironless motor assembly 15 and U-channel magnet track 14 is nearly position independent.

Unfortunately, an ironless, U-channel linear motor also has some inherent limitations that negatively affect the achievable accuracy and throughput of a wafer positioning system, such as wafer positioning system 10 depicted in FIG. 1. Due to their ironless design, the amount of driving force generated for a given amount of electrical current flow is significantly less than an iron-core design. Despite optimization of the design of the ironless motor windings and the magnetic field strength, ironless, U-channel linear motors require significantly more electrical current flow to generate the same linear driving force as a comparable iron-core linear motor. Electrical current flow through an electrically conductive material generates heat, and the heat generated must be dissipated somewhere, often at the cost of wafer positioning accuracy. For example, as depicted in FIG. 1, the ironless motor assembly 15 is mechanically fixed to the intermediate frame 12. Heat generated in the coil windings of ironless motor assembly 15 conducts into the intermediate frame 12. As depicted in FIG. 1, arrow 16 represents a flow of heat from ironless motor assembly 15 into intermediate frame 12. The temperature of intermediate frame 12 rises as heat flow 16 is absorbed. The authors have observed an increase in temperature of an intermediate frame of approximately 0.65 degrees Centigrade under normal operating conditions within a high throughput optical metrology tool. This increase in temperature causes material expansion and deformation that severely limits positioning repeatability at the wafer.

FIG. 2 is a simplified diagram illustrative of a typical prior art wafer positioning system 20 in another embodiment. Wafer positioning system 20 includes a stage base frame 21 and an intermediate frame 22. Coordinate frame {X_{IF}, Y_{IF}, Z_{IF}} is fixed to intermediate frame 22. A set of mechanical linear bearings 23 constrain the relative motion of intermediate frame 22 with respect to stage base frame 21 to one degree of freedom, i.e., the Y_{IF}-direction. To address the limited force generating potential of U-channel, ironless linear motors, wafer positioning system 20 employs an iron-core linear motor. FIG. 2 illustrates an iron-core linear motor including a magnet track 24 and an iron-core motor assembly 25. As depicted in FIG. 2, the iron-core motor assembly 25 is mechanically fixed to the intermediate frame 22 and the magnet track 24 is mechanically fixed to the stage base frame 21. The iron-core motor assembly 25 includes multiple electrically conductive wire coils each wrapped around a ferrous post. Typically, each ferrous post is fabricated as part of a larger ferrous structure. In some examples, the copper coils are embedded in an epoxy matrix material that fills the space around the conductive wire coils and the ferrous structure. The magnet track 24 includes multiple permanent magnets 27 attached to a magnetic backing plate mechanically fixed to the stage base frame 21. This assembly generates a magnetic field in the space above magnet track 24. As depicted in FIG. 2, magnetic field lines 27 are concentrated in the permanent magnets and ferrous backing plate of the U-shaped magnet track 24, but extend in the space above magnet track 24. The portion of the magnetic field external to the flat magnet track 24 is expansive compared to the relatively small gap across the U-shaped channel of a U-channel, ironless linear motor.

As depicted in FIG. 2, the iron-core motor assembly 25 is located above the flat magnet track 24. Furthermore, the ferrous posts and associated ferrous structure shape the magnetic field lines 27, i.e., the magnetic field lines concentrate in the ferrous posts and associated structure. In this manner, the ferrous posts and structure define the shape of the magnetic field above the magnet track 24 and are a critical component of the magnetic circuit. This differs substantially from a U-channel, ironless linear motor. A mechanical driving force is generated in the Y-direction by flowing electrical current through the windings of the coils of the iron-core motor assembly 25. The concentration of magnetic lines in the ferrous posts and associated ferrous structure strengthens the magnetic field across the gap between the flat magnet track 24 and the iron-core motor assembly 25. As a result, the amount of driving force generated for a given amount of electrical current flow is significantly more than an ironless linear motor design. As a result, an iron-core linear motor is able to generate a larger driving force with less heat generation compared to a U-channel, ironless linear motor.

Unfortunately, the presence of ferrous content in the iron-core motor assembly 25 gives rise to a large attraction force between the magnet track 24 and the iron-core motor assembly 25 of an iron-core linear motor. As illustrated in FIG. 2, a large magnetic attraction force, F_{M}, acts on the iron-core motor assembly 25 and intermediate frame 21 in the Z_{IF} direction. Linear bearings 23 support intermediate frame 22 by applying restoring forces, F_{R1}, and F_{R2}, to balance the magnetic attraction force, F_{M}, and maintain the position of intermediate frame 22 in the Z_{IF}-direction. Due to the large magnetic attraction force imposed on the linear bearings, relatively large capacity linear bearings must be employed to avoid premature bearing failure. If mechanical bearing are employed, the relatively large bearings induce significant jitter to the position of intermediate frame 22 during motion. This can excite high frequency modes in the stage and increase settling time. In addition, the iron-core motor assembly 25 is physically separated from the linear bearings 23 by a significant distance, D. Thus, the magnetic attraction force, F_{M}, induces a substantial bending moment on intermediate frame 22. This bending moment induces substantial deformation of intermediate frame 22, which, in turn, results in decreased wafer positioning accuracy.

Finally, as depicted in FIG. 2, the iron-core motor assembly 25 is mechanically fixed to the intermediate frame 22. Heat generated in the coil windings of iron-core motor assembly 25 conducts into the intermediate frame 22. As depicted in FIG. 2, arrow 26 represents a flow of heat from iron-core motor assembly 25 into intermediate frame 22. The temperature of intermediate frame 22 rises as heat flow 26 is absorbed. Although, the heat generated by an iron-core motor assembly is less than an ironless motor assembly for the same driving force, the increase in temperature of the intermediate frame is still substantial, and this increase in temperature causes material expansion and deformation that severely limits positioning repeatability at the wafer.

Future metrology applications present challenges for metrology due to increasingly high measurement resolution and throughput requirements. Wafer positioning systems with higher accuracy and throughput capability are desired.

### SUMMARY

Methods and systems for realizing a high throughput wafer positioning system with high positioning accuracy are presented herein. The high throughput, high accuracy wafer positioning system is employed to measure structural and material characteristics (e.g., material composition, dimensional characteristics of structures and films, etc.) associated with different semiconductor fabrication processes.

In one aspect, iron core linear motor assemblies are arranged in a magnetically opposed configuration such that the magnetic attraction forces inherent to each opposing iron core linear motor assembly largely cancel one another. Thus, the net force applied to sensitive stage frame elements due to the magnetic attraction forces is negligible. The reduced force applied to sensitive stage frame elements, in turn, reduces induced deformations and stage positioning errors. Furthermore, the forces applied to bearing elements required to constrain the position of sensitive stage frame elements are also dramatically reduced.

In a further aspect, a wafer positioning system includes a second long stroke stage stacked on top of a magnetically opposed long stroke stage. In some embodiments, both stacked long stroke stages are configured as magnetically opposed stages. In some of these embodiments, both magnetically opposed long stroke stages employ magnet tracks mechanically coupled to the intermediate frame of the stacked stage assembly. As a result, the intermediate frame is thermally isolated from the heat generated by the iron-core motor assemblies of both long stroke stages by the magnetic gaps between the iron-core motor assemblies and the corresponding magnet tracks.

In a further aspect, an iron-core linear motor assembly includes one or more cooling channels within a housing of the assembly. A gaseous or liquid cooling fluid is pumped through the cooling channels to extract heat from the iron-core linear motor assembly.

In another further aspect, an iron-core linear motor assembly arranged as a moving magnet motor includes multiple sets of electrical coils each wired in series and driven by a separate electrical current driver operating at a different phase to minimize thermal transients during operation.

In a further aspect, measurements of one or more structures disposed on a semiconductor wafer are performed while positioning the wafer with a magnetically opposed, iron-core wafer positioning system. In general, any suitable model-based or modeless metrology technique may be employed to perform measurements of structures positioned by a magnetically opposed, iron-core wafer positioning system in accordance with the methods and systems described herein.

The foregoing is a summary and thus contains, by necessity, simplifications, generalizations and omissions of detail; consequently, those skilled in the art will appreciate that the summary is illustrative only and is not limiting in any way. Other aspects, inventive features, and advantages of the devices and/or processes described herein will become apparent in the non-limiting detailed description set forth herein.

### BRIEF DESCRIPTION OF THE DRAWINGS

FIG. 1 is a simplified diagram illustrative of a typical prior art wafer positioning system 10 in one embodiment.

FIG. 2 is a simplified diagram illustrative of a typical prior art wafer positioning system 10 in another embodiment.

FIG. 3 is a simplified diagram illustrative of a wafer positioning system 120 in a magnetically opposed configuration in one embodiment.

FIG. 4 is a diagram illustrative of a perspective view of wafer positioning system 150 including two stacked magnetically opposed long stroke stages in one embodiment.

FIG. 5 is a diagram illustrative of another perspective view of wafer positioning system 150 including two stacked magnetically opposed long stroke stages in one embodiment.

FIG. 6. is a simplified diagram illustrative of a cross-sectional view of an iron-core linear motor assembly in one embodiment.

FIG. 7A is a plot depicting a simulation of the temperature of a wafer frame of a wafer positioning system as the temperature rises from a start-up temperature at the beginning of operation to a steady state temperature under representative high throughput operating conditions.

FIG. 7B is a plot depicting a simulation of the temperature of an intermediate frame of a wafer positioning system as the temperature rises from a start-up temperature at the beginning of operation to a steady state temperature under representative high throughput operating conditions.

FIG. 7C is a plot depicting a simulation of the temperature of a stage base frame of a wafer positioning system as the temperature rises from a start-up temperature at the beginning of operation to a steady state temperature under representative high throughput operating conditions.

FIG. 8 is a diagram illustrative of a system 100 for performing spectroscopic ellipsometry measurements of one or more structures disposed on a semiconductor wafer, the system 100 employing a magnetically opposed, iron-core wafer positioning system.

FIG. 9 is a diagram illustrative of a system 200 for performing angle resolved spectroscopic reflectometry measurements of one or more structures disposed on a semiconductor wafer, the system 200 employing a magnetically opposed, iron-core wafer positioning system.

FIG. 10 is a diagram illustrative of a system 300 for performing spectroscopic reflectometry measurements of one or more structures disposed on a semiconductor wafer, the system 300 employing a magnetically opposed, iron-core wafer positioning system.

FIG. 11 is a flowchart of a method of positioning a wafer with a magnetically opposed, iron-core wafer positioning system as described herein.

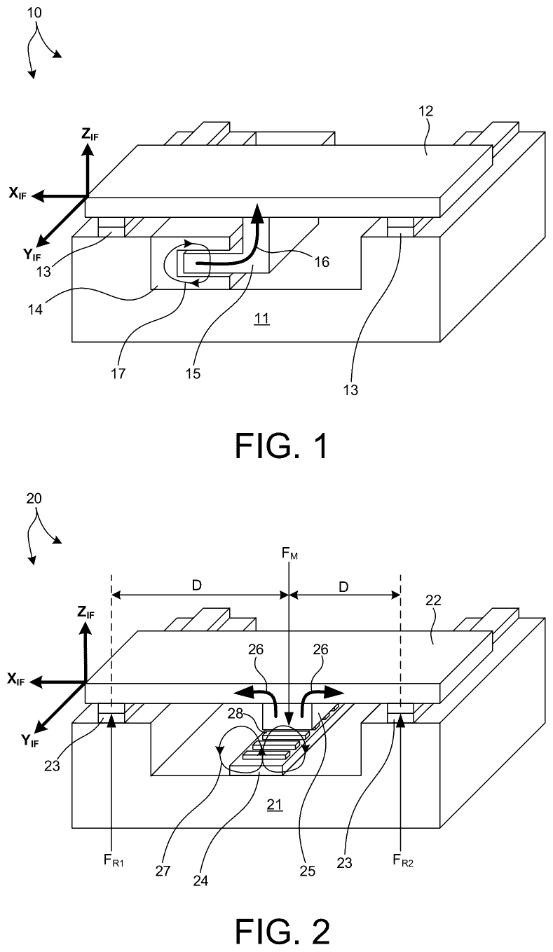

### DETAILED DESCRIPTION

Reference will now be made in detail to background examples and some embodiments of the invention, examples of which are illustrated in the accompanying drawings.

Methods and systems for realizing a high throughput wafer positioning system with high positioning accuracy are presented herein. The high throughput, high accuracy wafer positioning system is employed to measure structural and material characteristics (e.g., material composition, dimensional characteristics of structures and films, etc.) associated with different semiconductor fabrication processes.

In one aspect, iron core linear motor assemblies are arranged in a magnetically opposed configuration such that the magnetic attraction forces inherent to each opposing iron core linear motor assembly largely cancel one another. Thus, the net force applied to sensitive stage frame elements due to the magnetic attraction forces is negligible. The reduced force applied to sensitive stage frame elements, in turn, reduces induced deformations and stage positioning errors. Furthermore, the forces applied to bearing elements required to constrain the position of sensitive stage frame elements are also dramatically reduced. This increases bearing lifetime and enables the implementation of smaller bearing elements, which reduces induced friction and bearing induced positioning jitter.

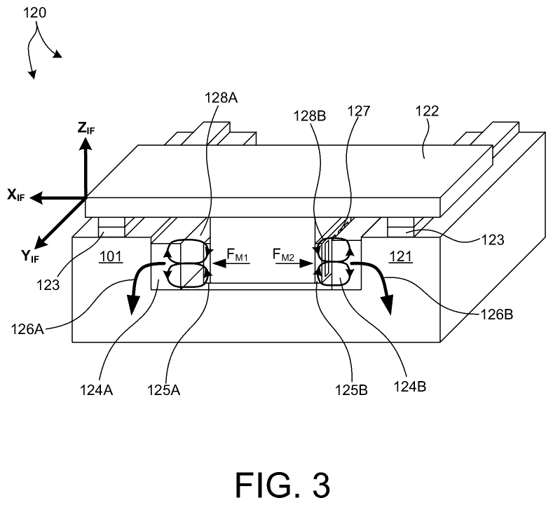

FIG. 3 is a simplified diagram illustrative of a wafer positioning system 120 in a magnetically opposed configuration in one embodiment. Wafer positioning system 120 includes a stage base frame 121 and an intermediate frame 122. Coordinate frame {X_{IF}, Y_{IF}, Z_{IF}} is fixed to intermediate frame 122. A set of mechanical linear bearings 123 constrain the relative motion of intermediate frame 122 with respect to stage base frame 121 to one degree of freedom, i.e., the Y_{IF}-direction.

In the embodiment depicted in FIG. 3, wafer positioning system 120 employs a pair of iron-core linear motors in a magnetically opposed configuration. FIG. 3 illustrates a pair of iron-core motor assemblies 124A-B and a corresponding pair of magnet tracks 125A-B. As depicted in FIG. 3, the iron-core motor assemblies 124A-B are mechanically fixed to the stage base frame 121 and the pair of magnet tracks 125A-B are mechanically fixed to the stage intermediate frame 122. As depicted in FIG. 3, magnet tracks 125A-B are positioned such that the face of each magnet track of the pair of magnet tracks is facing in the opposite direction. Each magnet track includes multiple permanent magnets 127 attached to a magnetic backing plate mechanically fixed to the intermediate frame 122. Each magnet track generates a magnetic field in the space adjacent to the face of the magnet track. The face of a magnet track is defined by the sides of the array of permanent magnets exposed to the environment opposite the magnetic backing plate of the magnet track.

Magnet track 125A includes multiple permanent magnets attached to a magnetic backing plate mechanically fixed to the intermediate frame 122. This assembly generates a magnetic field in the space adjacent to magnet track 125A. As depicted in FIG. 3, magnetic field lines 128A are concentrated in the permanent magnets and ferrous backing plate of magnet track 125A, and extend in the space adjacent to magnet track 125A. Similarly, magnet track 125B includes multiple permanent magnets 127 attached to a magnetic backing plate mechanically fixed to the intermediate frame 122. This assembly generates a magnetic field in the space adjacent to magnet track 125B. As depicted in FIG. 3, magnetic field lines 128B are concentrated in the permanent magnets and ferrous backing plate of magnet track 125B, and extend in the space adjacent to magnet track 125B.

The iron-core motor assemblies 124A-B include multiple electrically conductive wire coils each wrapped around a ferrous post. Each ferrous post is fabricated as part of a larger ferrous structure. In some examples, the copper coils are embedded in an epoxy matrix material that fills the space around the conductive wire coils and the ferrous structure.

As depicted in FIG. 3, the iron-core motor assemblies 124A-B are located adjacent to the faces of magnet tracks 125A-B, respectively. Furthermore, the ferrous posts and associated ferrous structure shape the magnetic field lines 128A-B, respectively, i.e., the magnetic field lines concentrate in the ferrous posts and associated structure. A mechanical driving force is generated in the Y_{IF}-direction by flowing electrical current through the windings of the coils of the iron-core motor assemblies 124A-B.

As described hereinbefore, an iron-core linear motor is able to generate a larger driving force with less heat generation compared to a U-channel, ironless linear motor. However, the presence of ferrous content in the iron-core motor assemblies 124A-B gives rise to large attraction forces between magnet tracks 125A-B and iron-core motor assemblies 124A-B. As illustrated in FIG. 3, a large magnetic attraction force, F_{M1}, acts on magnet track 125A and intermediate frame 122 in the positive X_{IF} direction. Similarly, a large magnetic attraction force, F_{M2}, acts on magnet track 125B and intermediate frame 122 in the negative X_{IF} direction, opposite the direction of magnetic attraction force, F_{M1}.

In general, the magnetic attraction force of an iron-core linear motor is largely dependent on the magnetic flux density in the gap between the magnet track and the iron-core motor assembly, which, in turn, strongly depends on the size of the gap. In practice, wafer positioning stage 120 is designed to maintain a constant gap between magnet track 125A and iron-core motor assembly 124A that is similar to a constant gap between magnet track 125B and iron-core motor assembly 124B. The gaps are dictated by machine tolerances and maintained by linear bearings 123 over the workspace of wafer positioning stage 120. Assuming similar gaps are maintained, the magnetic attraction forces, F_{M1} and F_{M2}, are approximately the same, and cancel each other. As a result, the residual force applied to intermediate frame 122 due to magnetic attraction forces, F_{M1} and F_{M2}, is negligible, along with any residual bending moment applied to intermediate frame 122. This dramatically reduces any induced deformation of intermediate frame 122, which, in turn, results in increased wafer positioning accuracy.

In addition, the forces applied to linear bearings 123 are dramatically reduced because the magnetic attraction forces, F_{M1} and F_{M2}, largely cancel one another. As a result, much smaller linear bearings can be employed. For mechanical bearings, a smaller size bearing can be employed without sacrificing bearing lifetime. Smaller sized mechanical bearings operate with reduced friction and reduced positioning jitter. This enables improved stage positioning repeatability and reduced settling times.

Finally, as depicted in FIG. 3, the iron-core motor assemblies 124A-B are mechanically fixed to the stage base frame 101. Heat generated in the coil windings of iron-core motor assemblies 124A-B conducts into the stage base frame 101. As depicted in FIG. 3, arrows 126A-B represent a flow of heat from iron-core motor assemblies 124A-B, respectively, into stage base frame 101, rather than intermediate frame 122. As a result, the temperature of intermediate frame 122 does not change substantially during stage operation and induced material expansion and deformation of intermediate frame 122 is negligible. This enables dramatically improved positioning repeatability of the stage at the wafer level.

In a further aspect, a wafer positioning system includes a second long stroke stage stacked on top of a magnetically opposed long stroke stage, such as the magnetically opposed long stroke stage depicted in FIG. 3. In some embodiments, both stacked long stroke stages are configured as magnetically opposed stages. In other embodiments, only the bottom long stroke stage, i.e., the stage mounted to the stage base frame, is configured as a magnetically opposed long stroke stage.

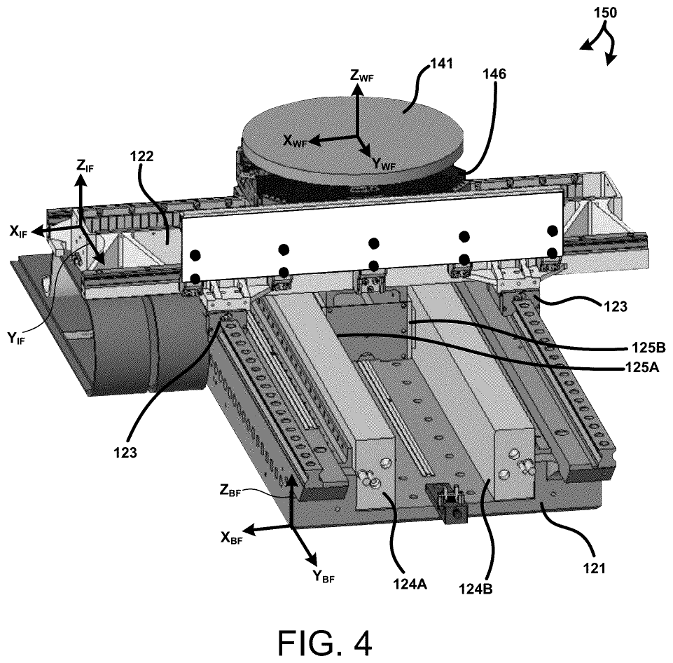

FIG. 4 is a diagram illustrative of a perspective view of wafer positioning system 150 including two stacked magnetically opposed long stroke stages in one embodiment.

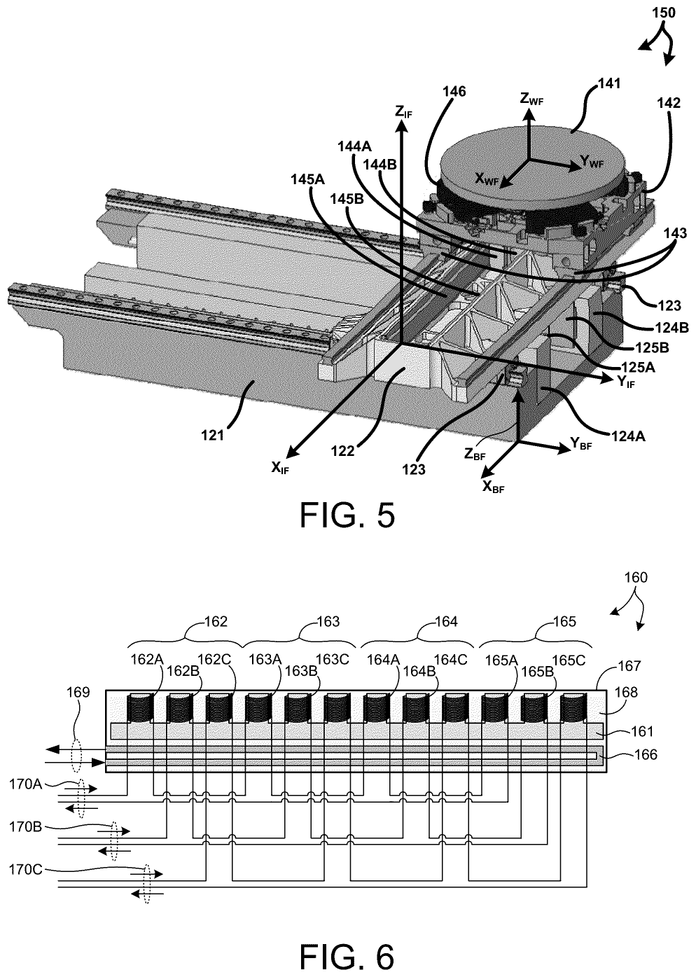

FIG. 5 is a diagram illustrative of another perspective view of wafer positioning system 150 including two stacked magnetically opposed long stroke stages in one embodiment.

As depicted in FIGS. 4 and 5, wafer positioning system 150 includes a stage base frame 121, an intermediate frame 122, and a wafer frame 142. Coordinate frame {X_{BF}, Y_{BF}, Z_{BF}} is fixed to stage base frame 121, coordinate frame {X_{IF}, Y_{IF}, Z_{IF}} is fixed to intermediate frame 122, and coordinate frame {X_{WF}, Y_{WF}, Z_{WF}} is fixed to wafer frame 142. A set of linear bearings 123 constrain the relative motion of intermediate frame 122 with respect to stage base frame 121 to one degree of freedom, i.e., the Y_{IF}-direction. A set of linear bearings 143 constrain the relative motion of wafer frame 142 with respect to intermediate frame 122 to one degree of freedom, i.e., the X_{WF}-direction.

In the embodiment depicted in FIGS. 4 and 5, wafer positioning system 150 employs a pair of iron-core linear motors in a magnetically opposed configuration to provide the driving force required to position intermediate frame 122 with respect to stage base frame 121 in the Y_{IF}-direction, and another pair of iron-core linear motors in a magnetically opposed configuration to provide the driving force required to position wafer frame 142 with respect to intermediate frame 122 in the X_{WF}-direction.

FIGS. 4 and 5 also illustrate a multi-degree of freedom short stroke positioning stage 146 mounted to wafer frame 142. In some embodiments, short stroke positioning stage 146 positions wafer chuck 141 in the Z_{WF} direction with respect to the wafer frame 142, and orients wafer chuck 141 about the Y_{WF}-axis and the X_{WF}-axis with respect to wafer frame 142. In these embodiments, short stroke positioning stage 146 is commonly referred to as a tip-tilt-Z stage. In some other embodiments, short stroke positioning stage 146 controls the position of wafer chuck 141 with respect to wafer frame 142 in additional degrees of freedom, e.g., orientation about the Z_{WF}-axis, position in the X_{WF} and Y_{WF} directions, or any combination thereof.

FIGS. 4 and 5 illustrate a pair of iron-core motor assemblies 124A-B and a corresponding pair of magnet tracks 125A-B in a magnetically opposed configuration as described with reference to FIG. 3. A mechanical driving force is generated in the Y_{IF}-direction by flowing electrical current through the windings of the coils of the iron-core motor assemblies 124A-B.

FIG. 5 illustrates iron-core motor assemblies 144A-B mechanically fixed to the wafer frame 142 and a corresponding pair of magnet tracks 145A-B mechanically fixed to intermediate frame 122. As depicted in FIG. 5, magnet tracks 145A-B are positioned such that the face of each magnet track of the pair of magnet tracks is facing in the opposite direction. Each magnet track includes multiple permanent magnets attached to a magnetic backing plate mechanically fixed to intermediate frame 122. Each magnet track generates a magnetic field in the space adjacent to the face of the magnet track. The face of a magnet track is defined by the sides of the array of permanent magnets exposed to the environment opposite the magnetic backing plate of the magnet track.

The iron-core motor assemblies 144A-B include multiple electrically conductive wire coils each wrapped around a ferrous post. Each ferrous post is fabricated as part of a larger ferrous structure. In some examples, the copper coils are embedded in an epoxy matrix material that fills the space around the conductive wire coils and the ferrous structure.

As depicted in FIG. 5, the iron-core motor assemblies 144A-B are located adjacent to the faces of magnet tracks 145A-B, respectively. Furthermore, the ferrous posts and associated ferrous structure of iron-core motor assembly 144A shape the magnetic field lines passing through the gap between iron-core motor assembly 144A and magnet track 145A. Similarly, the ferrous posts and associated ferrous structure of iron-core motor assembly 144B shape the magnetic field lines passing through the gap between iron-core motor assembly 144B and magnet track 145B. A mechanical driving force is generated in the X_{WF}-direction by flowing electrical current through the windings of the coils of the iron-core motor assemblies 144A-B.

The presence of ferrous content in the iron-core motor assemblies 144A-B gives rise to large attraction forces between magnet tracks 145A-B and iron-core motor assemblies 144A-B. A magnetic attraction force acts on iron-core motor assembly 144A in the negative Y_{WF}-direction due to the magnetic interaction between iron-core motor assembly 144A and magnet track 145A. Similarly, a magnetic attraction force acts on iron-core motor assembly 144B in the positive Y_{WF}-direction due to the magnetic interaction between iron-core motor assembly 144B and magnet track 145B. Since, the magnetic attraction forces act in opposite directions on iron-core motor assemblies 144A-B, respectively, and both iron-core motor assemblies 144A-B are mechanically fixed to wafer frame 142, the magnetic attraction forces cancel one another. Assuming similar gaps are maintained between iron-core motor assemblies 144A-B and magnet tracks 145A-B, respectively, the residual force applied to wafer frame 142 due to the magnetic attraction forces is negligible, along with any residual bending moment applied to wafer frame 142. This dramatically reduces any induced deformation of wafer frame 142, which, in turn, results in increased wafer positioning accuracy.

In addition, the forces applied to linear bearings 143 are dramatically reduced because the magnetic attraction forces largely cancel one another. As a result, much smaller linear bearings can be employed. For mechanical bearings, a smaller size bearing can be employed without sacrificing bearing lifetime. Smaller sized mechanical bearings operate with reduced friction and reduced positioning jitter. This enables improved stage positioning repeatability and reduced settling times.

Finally, as depicted in FIG. 5, the iron-core motor assemblies 144A-B are mechanically fixed to the wafer frame 142. Heat generated in the coil windings of iron-core motor assemblies 144A-B conducts into the wafer frame 142, rather than intermediate frame 122. As a result, the temperature of intermediate frame 122 does not change substantially during stage operation and induced material expansion and deformation of intermediate frame 122 is negligible. This enables improved positioning repeatability of the stage at the wafer level.

As depicted in FIGS. 4 and 5, both magnetically opposed long stroke stages of wafer positioning system 150 employ magnet tracks mechanically coupled to the intermediate frame 122. As a result, the intermediate frame 122 is thermally isolated from the heat generated by iron-core motor assemblies 124A-B and 144A-B by the physical gap between the iron-core motor assemblies and the corresponding magnet tracks. A small amount of heat transfer occurs via linear bearings 123 and 143, but the mechanical contact area of the linear bearings is quite small, and thus the total amount of heat transfer is negligible. In some embodiments, air bearings, porous or orifice type air bearings, may be employed instead of mechanical bearings, e.g., roller bearings or ball bearings. In these embodiments, the heat transfer through the air gap of the air bearings is negligible.

The coefficient of thermal expansion (CTE) of the steel structure of linear bearings 143 is not matched with the coefficient of thermal expansion of the aluminum intermediate plate 122. However, in the embodiment depicted in FIGS. 4 and 5, linear bearings 143 are mounted near the neutral axis of intermediate plate 122. The neutral axis of intermediate plate 122 is the axis in the cross section of intermediate plate 122 along which there are no longitudinal stresses or strains, i.e., longitudinal strain is not induced due to the CTE mismatch of the linear bearings and the intermediate frame 122 when a temperature change occurs. Thus, the small amount of temperature change of the intermediate frame 122 and linear bearings 143 does not induce significant deformation of intermediate frame 122.

Wafer positioning system 150 includes two stacked, magnetically opposed long stroke stages. Each magnetically opposed, long stroke stage is able to move the wafer over a distance of at least 300 millimeters in the long stroke direction, i.e., the X and Y directions. Wafer positioning system 150 is able to position a wafer at any location in the workspace with a repeatability of less than 300 nanometers. To meet the high throughput requirements of a semiconductor fabrication facility, the wafer positioning system is able to generate high accelerations in both the X and Y directions. In some embodiments, wafer positioning system 150 accelerates a wafer with an acceleration of at least 30 meters/sec². In some embodiments, wafer positioning system 150 accelerates a wafer with an acceleration greater than 50 meters/sec². The moving mass of the Y-stage, i.e., the sum of the mass of the intermediate frame 122 and all components carried by the intermediate frame 122 is large, e.g., more than 40 kilograms. To accelerate such a mass at an acceleration of at least 30 meters/sec², iron-core linear motor assemblies 124A and 124B each generate at least 600 Newtons of force, continuously. To generate such large forces, iron-core linear motor assemblies 124A and 124B each generate a significant amount of heat.

In a further aspect, an iron-core linear motor assembly includes one or more cooling channels within a housing of the assembly. A gaseous or liquid cooling fluid is pumped through the cooling channels to extract heat from the iron-core linear motor assembly.

FIG. 6. is a diagram illustrative of a cross-sectional view of an iron-core linear motor assembly in one embodiment. Iron-core linear motor assembly 160 includes ferrous structure 161, coil sets 162-165, and cooling channel 166 integrated in a housing 167. In some embodiments, the space between ferrous structure 161, coil sets 162-165, and cooling channel 166 is filled with a cured material 168, e.g., epoxy. In some other embodiments, the housing is fabricated with voids to match ferrous structure 161, coil sets 162-165, and cooling channel 166, and, optionally, any residual space is filled with a cured material 168. In the embodiment depicted in FIG. 6, a cooling fluid 169 is pumped through channel 166 to extract heat from iron-core linear motor assembly 160.

As described hereinbefore, the iron-core linear motor assemblies 124A-B of wafer positioning system 150 generate the most heat due to the high acceleration requirements and high payload of the long stroke Y-stage. As such, a significant amount of cooling fluid, either gaseous or fluid, is circulated through cooling channels of iron-core linear motor assemblies 124A-B. The cooling channels of iron-core linear motor assemblies 124A-B are directly coupled to the source of cooling fluid, e.g., a heat exchanger, a house supplied cooling source, etc. The direct connection is possible because the iron-core linear motor assemblies 124A-B are mechanically coupled to the stage base frame 121, which is not moving substantially with respect to the measurement system frame sitting in the wafer fabrication facility.

In some other embodiments, the iron-core linear motor assemblies 124A-B of wafer positioning system 150 are mounted to the intermediate plate 122. In these embodiments, flexible tubes are required to supply the cooling fluid to the iron-core linear motor assemblies 124 as the intermediate plate 122 moves with respect to the stage base frame 121. This embodiment is not preferred because the reliability of the flexible tubes is low and the substantial mass and hysteretic nature of the flexible tubes negatively impacts positioning accuracy and settling times of the wafer positioning system.

In some embodiments, flexible tubes are required to supply the cooling fluid to iron-core linear motor assemblies 144A-B of wafer positioning system 150. Although, it is preferred not to provide cooling to the X-stage, the amount of moving mass of the X-stage is much smaller than the Y-stage. As a result, the amount of cooling required is much smaller along with the size of the flexible tubes that must be routed from the stage base frame 101 to wafer frame 142 via intermediate frame 122. As a result, the force disturbance to wafer frame 142 from the flexible tubes is limited, and does not substantially affect the positioning accuracy and settling times of the wafer positioning system.

In a further aspect, an iron-core linear motor assembly arranged as a moving magnet motor includes multiple sets of electrical coils each wired in series and driven by a separate electrical current driver operating at a different phase to minimize thermal transients during operation of wafer positioning system 150.

As depicted in FIG. 6, ferrous structure 161 includes a number of pole pieces. In some embodiments, ferrous structure 161 is fabricated from laminated sheets of electrical steel to minimize power loss due to induced eddy currents. A coil of electrically conductive wire, e.g., copper wire, is wrapped around each pole piece. In the embodiment depicted in FIG. 6, the electrical coils are grouped into sets 162-165. Each set includes three adjacent coils that each operate in a different electrical phase to enable the moving portion of the linear motor to travel over its full stroke.

As depicted in FIG. 6, the first coil of each coil set, e.g., coils 162A-165A, are electrically coupled in series with a first controlled electrical current source. Similarly, the second coil of each coil set, e.g., coils 162B-165B, are electrically coupled in series to a second electrical current source, and the third coil or each coil set, e.g., coils 162C-165C, are electrically coupled in series to a third electrical current source. Electrical current 170A is provided through electrical coils 162A-165A, electrical current 170B is provided through electrical coils 162B-165B, and electrical current 170C is provided through electrical coils 162C-165C. Electrical currents 170A-C operate out of phase with one another to smoothly drive the linear motor independent of the relative position of iron-core linear motor assembly 160 with respect to the corresponding magnet track. By operating all coils of the same phase together, the entire coil assembly of the iron-core linear motor assembly 160 is heated uniformly, thereby eliminating possible moving hot spots.

In some other embodiments, each adjacent coil operates independently in a different electrical phase to enable the moving portion of the linear motor to travel over its full stroke. In this approach, the current flow through each electrical coil is independently controlled based on the position of the mover with respect to the stator element of the linear motor. This control approach is commonly referred to as coil switching. In these embodiments, current is only supplied to electrical coils that are positioned opposite a magnet track, and thus, are able to generate significant driving force. This approach results in less overall heat generation, but the heating is not uniform along the full length of the iron-core linear motor assembly. In general, the impact of non-uniform heating on overall positioning accuracy exceeds the impact of overall heating on overall positioning accuracy.

Iron-core linear motor assembly 160 is a three phase motor, i.e., three different sets of coils are wired in series and are driven by a separate electrical current driver operating one hundred and twenty degrees out of phase from the other sets of coils. However, in general, an iron-core linear motor assembly may be configured to operate in any number of different phases.

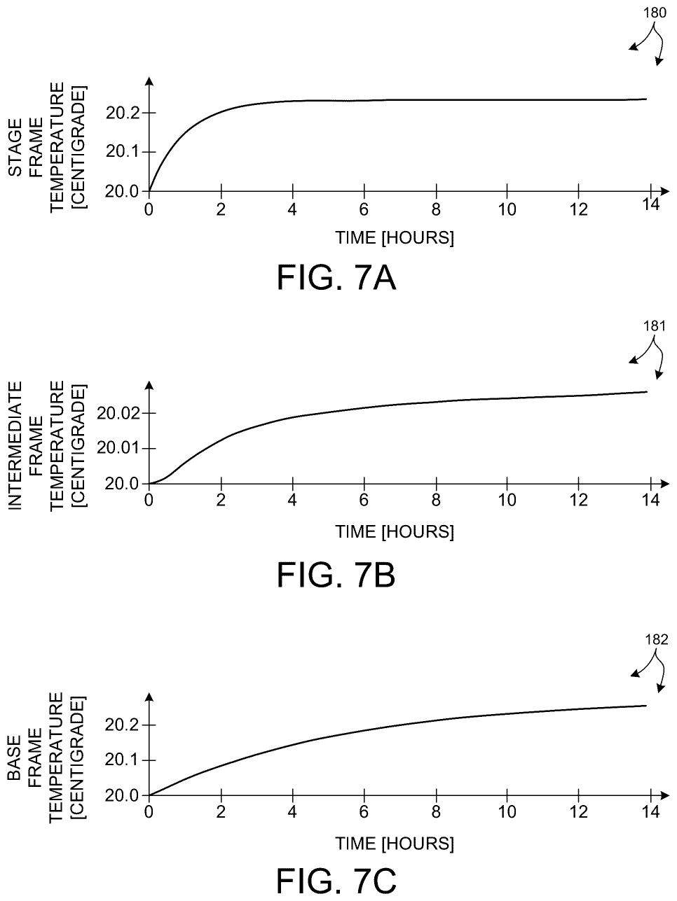

FIG. 7A is a plot 180 depicting a simulation of the temperature of wafer frame 142 of wafer positioning system 150 as the temperature of wafer frame 142 rises from a start-up temperature at the beginning of operation to a steady state temperature under representative high throughput operating conditions. As depicted in FIG. 7A, the temperature of wafer frame 142 rises approximately 0.23 degrees Centigrade. This is similar to a conventional stacked stage design employing U-channel, ironless linear motors.

FIG. 7B is a plot 181 depicting a simulation of the temperature of intermediate frame 122 of wafer positioning system 150 as the temperature of intermediate frame 122 rises from a start-up temperature at the beginning of operation to a steady state temperature under representative high throughput operating conditions. As depicted in FIG. 7B, the temperature of intermediate frame 122 rises approximately 0.023 degrees Centigrade. The comparable temperature increase of a conventional stacked stage design employing U-channel, ironless linear motors is more than 30× greater. The temperature stability of the intermediate frame 122 achieved using magnetically opposed iron-core linear motors as described herein enables significantly improved wafer positioning performance. By limiting heat transfer to intermediate frame 122, thermally induced Abbe error at the wafer is dramatically reduced. Furthermore, the thermal stability of intermediate frame 122 enables high wafer positioning accuracy after error mapping.

FIG. 7C is a plot 182 depicting a simulation of the temperature of stage base frame 121 of wafer positioning system 150 as the temperature of stage base frame 121 rises from a start-up temperature at the beginning of operation to a steady state temperature under representative high throughput operating conditions. As depicted in FIG. 7C, the temperature of stage base frame 121 rises approximately 0.027 degrees Centigrade. The large thermal mass of the stage base frame allows the absorption of significant heat generated by the iron-core linear motor assemblies 124A-B without inducing a significant change in the temperature of the stage base frame 121.

In general, the stage base frame of a magnetically opposed, iron-core wafer positioning system is attached to the machine frame of a measurement system. In this manner, the magnetically opposed, iron-core wafer positioning system is configured to accurately position a wafer under measurement with respect to optical subsystem of the measurement system.

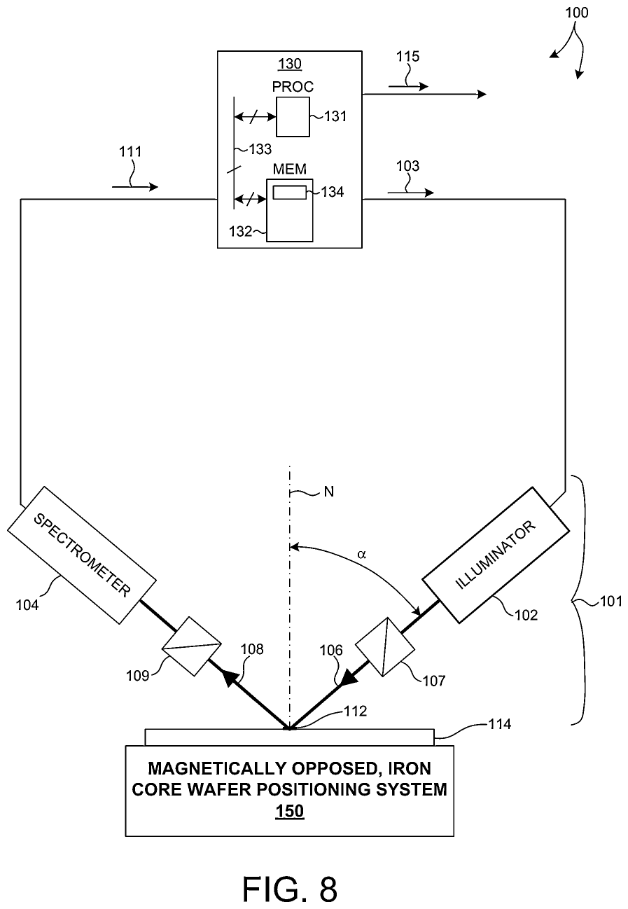

FIG. 8 illustrates a system 100 for measuring characteristics of a semiconductor wafer. As shown in FIG. 8, system 100 performs spectroscopic ellipsometry measurements of one or more structures 112 disposed on a semiconductor wafer 114 positioned with respect to the spectroscopic ellipsometer 101 by a magnetically opposed, iron-core wafer positioning system.

In this aspect, system 100 includes a spectroscopic ellipsometer 101 equipped with an illuminator 102 and a spectrometer 104. The illuminator 102 of the system 100 is configured to generate and direct illumination of a selected wavelength range (e.g., 100 nanometers-20 micrometers) to the one or more structures 112 disposed on the surface of the semiconductor wafer 114. In turn, the spectrometer 104 is configured to receive light from the surface of the semiconductor wafer 114. It is further noted that the light emerging from the illuminator 102 is polarized using a polarization state generator 107 to produce a polarized illumination beam 106. The radiation reflected by the structure 114 disposed on the wafer 112 is passed through a polarization state analyzer 109 and to the spectrometer 104. The radiation received by the spectrometer 104 in the collection beam 108 is analyzed with regard to polarization state, allowing for spectral analysis of radiation passed by the analyzer. The detected spectra 111 are passed to the computing system 130 for analysis of the one or more structures 112.

As depicted in FIG. 8, metrology system 100 includes a magnetically opposed, iron-core wafer positioning system 150 configured to locate wafer 114 with respect to spectrometer 101 during measurement. Magnetically opposed, iron-core wafer positioning system 150 receives command signals (not shown) from computing system 130. The command signals include an indication of a desired position of wafer 114 with respect to spectrometer 101. In response to the command signals, magnetically opposed, iron-core wafer positioning system 150 moves wafer 114 to the desired position with respect to spectrometer 101.

In one aspect, spectral ellipsometry measurements are performed while wafer 114 is located at the desired position with respect to spectrometer 101. The measurement data 111 collected from the measurements is communicated to computing system 130 and an estimate of one or more structural parameters of interest 115 is made based on the collected measurement data. Computing system 130 is configured to receive measurement data 111 associated with a measurement (e.g., critical dimension, film thickness, concentration, composition, process, etc.) of one or more structures 112 disposed on wafer 114. In one example, the measurement data 111 includes an indication of the measured spectral response of the specimen by measurement system 100 based on the one or more sampling processes from the spectrometer 104. In some embodiments, computing system 130 is further configured to determine specimen parameter values 115 of structure 112 from measurement data 111. In one example, the computing system 130 is configured to access model parameters in real-time, employing Real Time Critical Dimensioning (RTCD), or it may access libraries of pre-computed models for determining a value of at least one parameter of interest associated with the target structure 112. In some embodiments, the estimated values of the one or more parameters of interest are stored in a memory (e.g., memory 132). In the embodiment depicted in FIG. 8, the estimated values 115 of the one or more parameters of interest are communicated to an external system (not shown).

In general, ellipsometry is an indirect method of measuring physical properties of the specimen under inspection. In most cases, the raw measurement signals (e.g., αₘₑₐₛ and βₘₑₐₛ) cannot be used to directly determine the physical properties of the specimen. The nominal measurement process consists of parameterization of the structure (e.g., film thicknesses, critical dimensions, material properties, etc.) and the machine (e.g., wavelengths, angles of incidence, polarization angles, etc.). A measurement model is created that attempts to predict the measured values (e.g., (αₘₑₐₛ and βₘₑₐₛ). As illustrated in equations (1) and (2), the model includes parameters associated with the machine (P_{machine}) and the specimen (P_{specimen}).

α_{model}=f(P_{machine},P_{specimen}) (1)

β_{model}=g(P_{machine},P_{specimen}) (2)

Machine parameters are parameters used to characterize the metrology tool (e.g., ellipsometer 101). Exemplary machine parameters include angle of incidence (AOI), analyzer angle (A₀), polarizer angle (P₀), illumination wavelength, numerical aperture (NA), compensator or waveplate (if present), etc. Specimen parameters are parameters used to characterize the specimen (e.g., wafer 114 including structures 112). For a thin film specimen, exemplary specimen parameters include refractive index, dielectric function tensor, nominal layer thickness of all layers, layer sequence, etc. For a CD specimen, exemplary specimen parameters include geometric parameter values associated with different layers, refractive indices associated with different layers, etc. For measurement purposes, the machine parameters are treated as known, fixed parameters and one or more of the specimen parameters are treated as unknown, floating parameters.

In some examples, the floating parameters are resolved by an iterative process (e.g., regression) that produces the best fit between theoretical predictions and experimental data. The unknown specimen parameters, P_{specimen}, are varied and the model output values (e.g., α_{model} and β_{model}) are calculated until a set of specimen parameter values are determined that results in a close match between the model output values and the experimentally measured values (e.g., (αₘₑₐₛ and βₘₑₐₛ). In a model based measurement application such as spectroscopic ellipsometry on a CD specimen, a regression process (e.g., ordinary least squares regression) is employed to identify specimen parameter values that minimize the differences between the model output values and the experimentally measured values for a fixed set of machine parameter values.

In some examples, the floating parameters are resolved by a search through a library of pre-computed solutions to find the closest match. In a model based measurement application such as spectroscopic ellipsometry on a CD specimen, a library search process is employed to identify specimen parameter values that minimize the differences between pre-computed output values and the experimentally measured values for a fixed set of machine parameter values.

In a model-based measurement application, simplifying assumptions often are required to maintain sufficient throughput. In some examples, the truncation order of a Rigorous Coupled Wave Analysis (RCWA) must be reduced to minimize compute time. In another example, the number or complexity of library functions is reduced to minimize search time. In another example, the number of floating parameters is reduced by fixing certain parameter values. In some examples, these simplifying assumptions lead to unacceptable errors in the estimation of values of one or more parameters of interest (e.g., critical dimension parameters, overlay parameters, etc.). By performing measurements of structures subject to gaseous adsorption as described herein, the model-based measurement model can be solved with reduced parameter correlations and increased measurement accuracy.

In general, spectroscopic ellipsometer 101 may employ any architecture suitable to measure a modulation of optical properties, e.g., dielectric function, bandgap, etc. By way of non-limiting example, spectroscopic ellipsometer 101 may be configured with a rotating polarizer, rotating compensator, or any combination thereof.

Furthermore, the embodiments of the system 100 illustrated in FIG. 8 may be further configured as described herein. In addition, the system 100 may be configured to perform any other block(s) of any of the method embodiment(s) described herein.

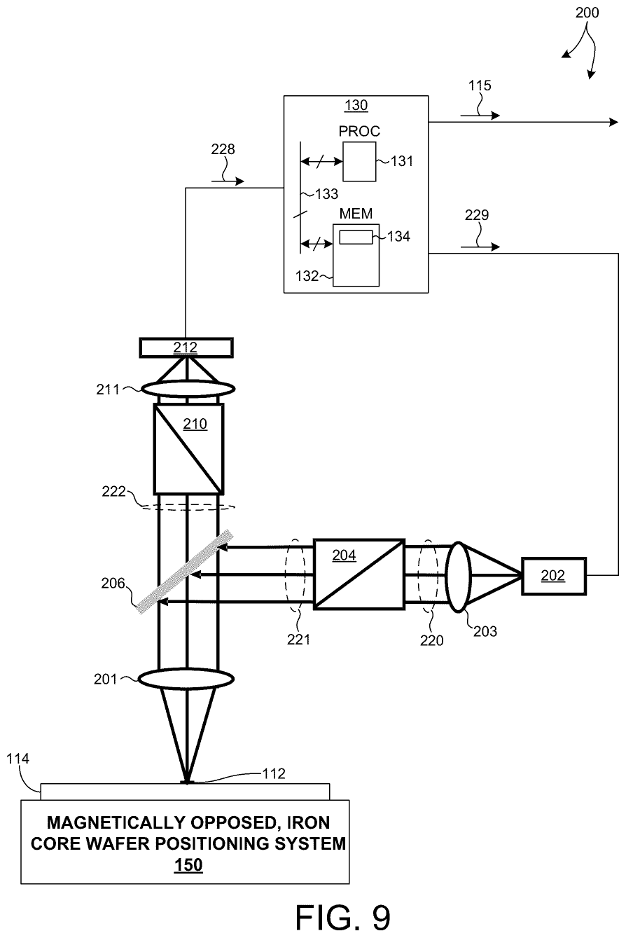

FIG. 9 illustrates an angle-resolved spectral reflectometer system configured to measure reflectivity over a wide angular range to estimate values of one or more characteristics of a semiconductor wafer in at least one novel aspect. Like numbered elements illustrated in FIG. 9 are analogous to those described with reference to FIG. 8. As shown in FIG. 9, system 200 performs angle resolved spectroscopic reflectometry measurements of one or more structures 112 disposed on a semiconductor wafer 114 positioned with respect to the angle resolved spectroscopic reflectometer by a magnetically opposed, iron-core wafer positioning system. In one embodiment, system 200 is an angle resolved spectroscopic reflectometer including one or more measurement channels spanning a broad wavelength range, e.g., infrared wavelengths between 750 nanometers and 2600 nanometers.

Angle resolved spectroscopic reflectometer 200 includes polarizer 204, objective 201, analyzer 210, and spectrometer 212. As depicted in FIG. 9, an illumination beam is generated by the illumination source 202 in response to command signals 229 received from computing system 130. Light from illumination source 202 is conditioned by optional beam forming optics 203 to generate an illumination light beam 220. Illumination light beam 220 is directed to polarizer 204. Although, as depicted, illumination light directed to polarizer 204 comes from illumination source 202, in general, light from any number of illumination sources of system 200 may be combined to generate an illumination light beam directed to polarizer 204. In this manner, the spectral components of the illumination light can be configured as a combination of light emitted from multiple illumination sources.

In some embodiments, polarizer 204 is configured to selectively rotate a polarizing element about the optical axis of the illumination light beam 220. In general, polarizer 204 may include any polarizing element and system to rotate the polarizing element known in the art. For example, the polarizer 204 may include a polarizing element mechanically coupled to a rotational actuator. In one example, the polarizing element may be a Rochon prism. In another example, the polarizing element may include a beam displacer. Polarizer 204 is configured to operate within system 200 in either a rotationally active or rotationally inactive state. In one instance, a rotational actuator of polarizer 204 may be inactive such that the polarizing element remains rotationally fixed about the optical axis of illumination light 220. In another instance, the rotational actuator may rotate the polarizing element at a selected angular frequency, ωₚ, about the optical axis of the illumination light.

In some other embodiments, polarizer 204 is configured with a fixed polarization angle about the optical axis of the illumination light beam 220.

As depicted in FIG. 9, illumination light beam 220 passes through polarizer 204 while the rotational actuator rotates the polarizing element at the selected angular frequency, ωₚ. In this manner, polarizer 204 generates a polarized light beam 221 directed toward beamsplitter 206. Beamsplitter 206 directs the polarized light beam 221 towards objective 201.

In the embodiment depicted in FIG. 9, objective 201 focuses polarized light beam 221 the surface of wafer 114 over a range of angles of incidence. In some examples, polarized light beam 221 is focused onto the surface of wafer 114 within a range of angles of incidence between 0 and 40 degrees. In some examples, the polarized light beam 221 is focused onto the surface of wafer 114 at small angles of incidence results in a small illumination spot, e.g., less than 100 micrometers in diameter.

The interaction of the focused, polarized light beam 221 with wafer 114 modifies the polarization of the radiation by any of reflection, scattering, diffraction, transmission, or other types of processes. After interaction with the wafer 114, modified light 222 is collected by objective 201 and directed to beamsplitter 206. Beamsplitter 206 is configured to transmit modified light 222 toward analyzer 210. In the embodiment depicted in FIG. 9, analyzer 210 includes a polarizer element that remains rotationally fixed about the optical axis of modified light beam 222 while the modified light beam 222 passes through the analyzer 210 and optional beam focusing optics 211 to spectrometer 212. In spectrometer 212, the beam components having different wavelengths are refracted (e.g., in a prism spectrometer) or diffracted (e.g., in a grating spectrometer) in different directions to different detectors. The detectors may be a linear array of photodiodes, with each photodiode measuring radiation in a different wavelength range. The radiation received by the spectrometer 212 is analyzed with regard to polarization state, allowing for spectral analysis by the spectrometer of radiation passed by the polarizer 212. The measured spectra 228 are communicated to computing system 130. Computing system 130 is configured to receive signals 228 indicative of the measured spectral response of the structure of interest and estimate values of parameters of interest based on the measured spectral response.

As depicted in FIG. 9, metrology system 200 includes a magnetically opposed, iron-core wafer positioning system 150 configured to locate wafer 114 with respect to the angle resolved spectroscopic reflectometer during measurement. Magnetically opposed, iron-core wafer positioning system 150 receives command signals (not shown) from computing system 130. The command signals include an indication of a desired position of wafer 114 with respect to the angle resolved spectroscopic reflectometer. In response to the command signals, magnetically opposed, iron-core wafer positioning system 150 moves wafer 114 to the desired position with respect to the angle resolved spectroscopic reflectometer as described with respect to spectroscopic ellipsometer system 100 hereinbefore.

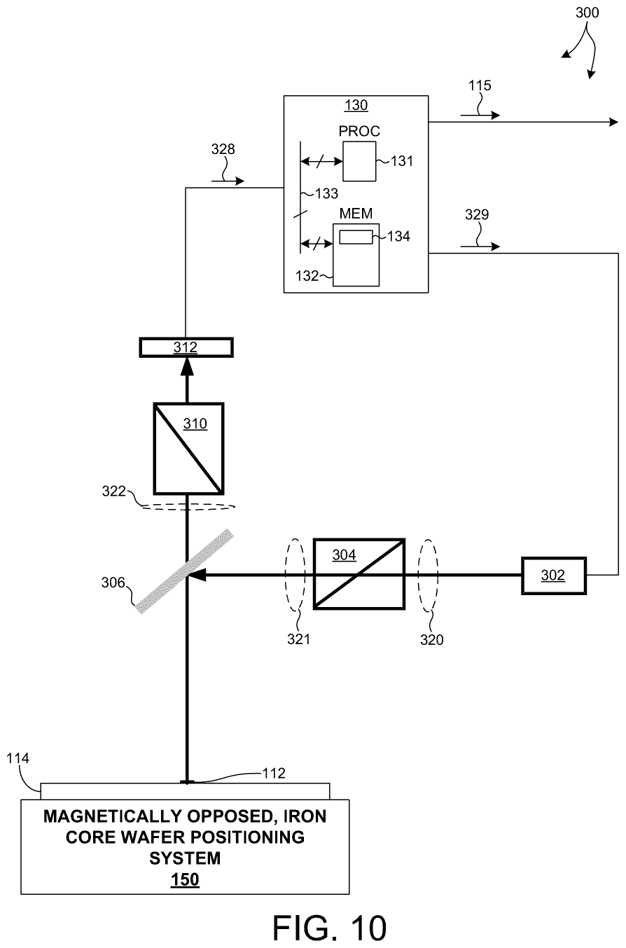

FIG. 10 illustrates a spectral reflectometer system configured to measure reflectivity at normal incidence to estimate values of one or more characteristics of a semiconductor wafer in at least one novel aspect. Like numbered elements illustrated in FIG. 10 are analogous to those described with reference to FIG. 8. As shown in FIG. 10, system 300 performs spectroscopic reflectometry measurements of one or more structures 112 disposed on a semiconductor wafer 114 positioned with respect to the spectroscopic reflectometer by a magnetically opposed, iron-core wafer positioning system.

Spectroscopic reflectometer 300 includes polarizer 304, analyzer 310, and spectrometer 312. As depicted in FIG. 10, an illumination beam is generated by the illumination source 302 in response to command signals 329 received from computing system 130. Illumination light beam 320 from illumination source 302 is directed to polarizer 304. Although, as depicted, illumination light directed to polarizer 304 comes from illumination source 302, in general, light from any number of illumination sources of system 300 may be combined to generate an illumination light beam directed to polarizer 304. In this manner, the spectral components of the illumination light can be configured as a combination of light emitted from multiple illumination sources.

In some embodiments, polarizer 304 is configured to selectively rotate a polarizing element about the optical axis of the illumination light beam 320. In general, polarizer 304 may include any polarizing element and system to rotate the polarizing element known in the art. For example, the polarizer 304 may include a polarizing element mechanically coupled to a rotational actuator. In one example, the polarizing element may be a Rochon prism. In another example, the polarizing element may include a beam displacer. Polarizer 304 is configured to operate within system 300 in either a rotationally active or rotationally inactive state. In one instance, a rotational actuator of polarizer 304 may be inactive such that the polarizing element remains rotationally fixed about the optical axis of illumination light 320. In another instance, the rotational actuator may rotate the polarizing element at a selected angular frequency, co p, about the optical axis of the illumination light.

In some other embodiments, polarizer 304 is configured with a fixed polarization angle about the optical axis of the illumination light beam 320.

As depicted in FIG. 10, illumination light beam 320 passes through polarizer 304 while the rotational actuator rotates the polarizing element at the selected angular frequency, W. In this manner, polarizer 304 generates a polarized light beam 321 directed toward beamsplitter 306. Beamsplitter 306 directs the polarized light beam 321 towards wafer 114 at normal incidence. The polarized light beam 221 is incident onto the surface of wafer 114 over a small illumination spot, e.g., less than 100 micrometers in diameter.

The interaction of the polarized light beam 221 with wafer 114 modifies the polarization of the radiation by any of reflection, scattering, diffraction, transmission, or other types of processes. After interaction with the wafer 114, modified light 322 is directed to beamsplitter 306. Beamsplitter 306 is configured to transmit modified light 322 toward analyzer 310. In the embodiment depicted in FIG. 10, analyzer 310 includes a polarizer element that remains rotationally fixed about the optical axis of modified light beam 322 while the modified light beam 322 passes through the analyzer 310 to spectrometer 312. In spectrometer 312, the beam components having different wavelengths are refracted (e.g., in a prism spectrometer) or diffracted (e.g., in a grating spectrometer) in different directions to different detectors. The detectors may be a linear array of photodiodes, with each photodiode measuring radiation in a different wavelength range. The radiation received by the spectrometer 312 is analyzed with regard to polarization state, allowing for spectral analysis by the spectrometer of radiation passed by the polarizer 312. The measured spectra 328 are communicated to computing system 130. Computing system 130 is configured to receive signals 328 indicative of the measured spectral response of the structure of interest and estimate values of parameters of interest based on the measured spectral response.

As depicted in FIG. 10, metrology system 300 includes a magnetically opposed, iron-core wafer positioning system 150 configured to locate wafer 114 with respect to the spectroscopic reflectometer during measurement. Magnetically opposed, iron-core wafer positioning system 150 receives command signals (not shown) from computing system 130. The command signals include an indication of a desired position of wafer 114 with respect to the spectroscopic reflectometer. In response to the command signals, magnetically opposed, iron-core wafer positioning system 150 moves wafer 114 to the desired position with respect to the spectroscopic reflectometer as described with respect to spectroscopic ellipsometer system 100 hereinbefore.

Although reflectometer systems 200 and 300 include polarization optics, in general, reflectometer system 200 and 300 may not include polarization optics.

In general, a measurement system may include any combination of spectroscopic ellipsometry measurements, spectral reflectometry measurements, and angle resolved spectral reflectometry measurements employing a magnetically opposed, iron-core wafer positioning system. The measurements may be performed sequentially or simultaneously.

In the embodiments depicted in FIGS. 8-10, measurements of one or more structures are performed while positioning a wafer with a magnetically opposed, iron-core wafer positioning system. In general, any suitable model-based or modeless metrology technique may be employed to perform measurements of structures positioned by a magnetically opposed, iron-core wafer positioning system in accordance with the methods and systems described herein.

Suitable metrology techniques include, but are not limited to, spectroscopic ellipsometry and spectroscopic reflectometry, including single wavelength, multiple wavelength, and angle resolved implementations, spectroscopic scatterometry, scatterometry overlay, beam profile reflectometry and beam profile ellipsometry, including angle-resolved and polarization-resolved implementations may be contemplated, individually, or in any combination.

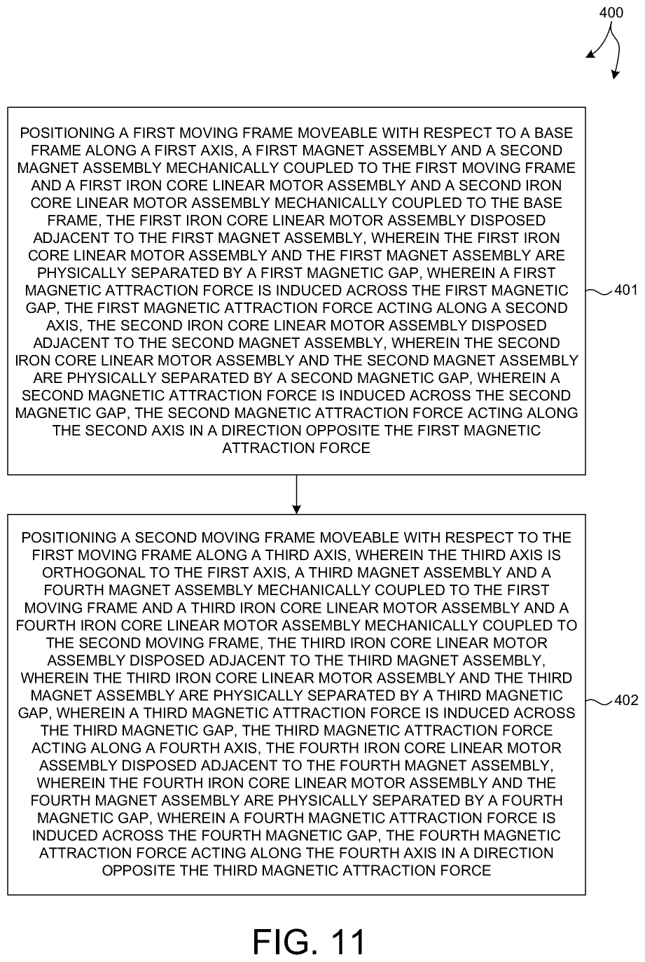

FIG. 11 illustrates a method 400 suitable for implementation by metrology systems 100, 200, and 300 of the present invention. In one aspect, it is recognized that any data processing elements of method 400 may be carried out via a pre-programmed algorithm executed by one or more processors of computing system 130. While the following description is presented in the context of metrology systems 100, 200, and 300, it is recognized herein that the particular structural aspects of metrology systems 100, 200, and 300 do not represent limitations and should be interpreted as illustrative only.

In block 301, a first moving frame is positioned with respect to a base frame along a first axis. A first magnet assembly and a second magnet assembly are mechanically coupled to the first moving frame. A first iron core linear motor assembly and a second iron core linear motor assembly are mechanically coupled to the base frame. The first iron core linear motor assembly is disposed adjacent to the first magnet assembly. The first iron core linear motor assembly and the first magnet assembly are physically separated by a first magnetic gap. A first magnetic attraction force is induced across the first magnetic gap. The first magnetic attraction force acts along a second axis. The second iron core linear motor assembly is disposed adjacent to the second magnet assembly. The second iron core linear motor assembly and the second magnet assembly are physically separated by a second magnetic gap. A second magnetic attraction force is induced across the second magnetic gap. The second magnetic attraction force acts along the second axis in a direction opposite the first magnetic attraction force.

In block 302, a second moving frame is positioned with respect to the first moving frame along a third axis. The third axis is orthogonal to the first axis. A third magnet assembly and a fourth magnet assembly are mechanically coupled to the first moving frame. A third iron core linear motor assembly and a fourth iron core linear motor assembly is mechanically coupled to the second moving frame. The third iron core linear motor assembly is disposed adjacent to the third magnet assembly. The third iron core linear motor assembly and the third magnet assembly are physically separated by a third magnetic gap. A third magnetic attraction force is induced across the third magnetic gap. The third magnetic attraction force acts along a fourth axis. The fourth iron core linear motor assembly is disposed adjacent to the fourth magnet assembly. The fourth iron core linear motor assembly and the fourth magnet assembly are physically separated by a fourth magnetic gap. A fourth magnetic attraction force is induced across the fourth magnetic gap. The fourth magnetic attraction force acts along the fourth axis in a direction opposite the third magnetic attraction force.

In general, the aforementioned measurement techniques may be applied to the measurement of process parameters, structural parameters, layout parameters, dispersion parameters, or any combination thereof. By way of non-limiting example, overlay, profile geometry parameters (e.g., critical dimension, height, sidewall angle), process parameters (e.g., lithography focus, and lithography dose), dispersion parameters, layout parameters (e.g., pitch walk, edge placement errors), film thickness, composition parameters, or any combination of parameters may be measured using the aforementioned techniques.

By way of non-limiting example, the structures measured with shape filling include gate all around structures, line-space grating structures, FinFet structures, SRAM device structures, Flash memory structures, and DRAM memory structures.

In another further aspect, the structures under measurement may be design rule targets. In other words, the metrology targets adhere to the design rules applicable to the underlying semiconductor manufacturing process. In some examples, the metrology targets are preferably located within the active die area. In some examples, the metrology targets have dimensions of 15 micrometers by 15 micrometers, or smaller. In some other examples, the metrology targets are located in the scribe lines, or otherwise outside the active die area.

In some examples, measurements of parameters of interest performed at a particular measurement site rely on data collected from that particular measurement site only, even though data may be collected from multiple sites on the wafer. In some other examples, measurement data collected from multiple sites across the wafer, or a subset of the wafer is used for measurement analysis. This may be desirable to capture parameter variations across the wafer.

In some examples, measurements of parameters of interest are performed based on metrology targets with multiple, different measurement techniques including single target techniques, multi-target techniques and spectra feedforward techniques. Accuracy of measured parameters may be improved by any combination of feed sideways analysis, feed forward analysis, and parallel analysis. Feed sideways analysis refers to taking multiple data sets on different areas of the same specimen and passing common parameters determined from the first dataset onto the second dataset for analysis. Feed forward analysis refers to taking data sets on different specimens and passing common parameters forward to subsequent analyses using a stepwise copy exact parameter feed forward approach. Parallel analysis refers to the parallel or concurrent application of a non-linear fitting methodology to multiple datasets where at least one common parameter is coupled during the fitting.

Multiple tool and structure analysis refers to a feed forward, feed sideways, or parallel analysis based on regression, a look-up table (i.e., “library” matching), or another fitting procedure of multiple datasets. Exemplary methods and systems for multiple tool and structure analysis is described in U.S. Pat. No. 7,478,019, issued on Jan. 13, 2009, to KLA-Tencor Corp., the entirety of which is incorporated herein by reference.

In yet another aspect, the measurement results obtained as described herein can be used to provide active feedback to a process tool (e.g., lithography tool, etch tool, deposition tool, etc.). For example, values of critical dimensions determined using the methods and systems described herein can be communicated to a lithography tool to adjust the lithography system to achieve a desired output. In a similar way etch parameters (e.g., etch time, diffusivity, etc.) or deposition parameters (e.g., time, concentration, etc.) may be included in a measurement model to provide active feedback to etch tools or deposition tools, respectively. In some example, corrections to process parameters determined based on measured device parameter values may be communicated to a lithography tool, etch tool, or deposition tool.

It should be recognized that the various steps described throughout the present disclosure may be carried out by a single computer system 130, a multiple computer system 130, or multiple, different computer systems 130. Moreover, different subsystems of systems 100, 200, and 300, such as the magnetically opposed, iron-core wafer positioning system, may include a computer system suitable for carrying out at least a portion of the steps described herein. Therefore, the aforementioned description should not be interpreted as a limitation on the present invention but merely an illustration. Further, computing system 130 may be configured to perform any other step(s) of any of the method embodiments described herein.

The computing system 130 may include, but is not limited to, a personal computer system, mainframe computer system, cloud-based computing system, workstation, image computer, parallel processor, or any other device known in the art. In general, the term “computing system” may be broadly defined to encompass any device, or combination of devices, having one or more processors, which execute instructions from a memory medium. In general, computing system 130 may be integrated with a measurement system such as measurement systems 100, 200, and 300, or alternatively, may be separate, entirely, or in part, from any measurement system. In this sense, computing system 130 may be remotely located and receive measurement data and from any measurement source and transmit command signals to any element of metrology systems 100, 200, and 300.

Program instructions 134 implementing methods such as those described herein may be transmitted over a transmission medium such as a wire, cable, or wireless transmission link. Memory 132 storing program instructions 134 may include a computer-readable medium such as a read-only memory, a random access memory, a magnetic or optical disk, or a magnetic tape.

In addition, the computing system 130 may be communicatively coupled to elements of measurement systems 100, 200, and 300 in any manner known in the art.

The computing system 130 may be configured to receive and/or acquire data or information from subsystems of a measurement system (e.g., spectrometer 104, illuminator 102, the magnetically opposed, iron-core wafer positioning system, and the like) by a transmission medium that may include wireline and/or wireless portions. In this manner, the transmission medium may serve as a data link between the computer system 130 and other subsystems of systems 100, 200, and 300. Further, the computing system 130 may be configured to receive measurement data via a storage medium (i.e., memory). For instance, the spectral results obtained using a spectrometer of ellipsometer 101 may be stored in a permanent or semi-permanent memory device (not shown). In this regard, the spectral results may be imported from an external system. Moreover, the computer system 130 may receive data from external systems via a transmission medium.

The computing system 130 may be configured to transmit data or information to subsystems of the system (e.g., spectrometer 104, illuminator 102, a magnetically opposed, iron-core wafer positioning system, and the like) by a transmission medium that may include wireline and/or wireless portions. In this manner, the transmission medium may serve as a data link between the computer system 130 and other subsystems of the systems 100, 200, and 300. Further, the computing system 130 may be configured to transmit command signals and measurement results via a storage medium (i.e., memory). For instance, the measurement results 115 obtained by analysis of spectral data may be stored in a permanent or semi-permanent memory device (not shown). In this regard, the spectral results may be exported to an external system. Moreover, the computer system 130 may send data to external systems via a transmission medium. In addition, the determined values of the parameter of interest are stored in a memory. For example, the values may be stored on-board the measurement systems 100, 200, and 300, for example, in memory 132, or may be communicated (e.g., via output signal 115) to an external memory device.

As described herein, the term “critical dimension” includes any critical dimension of a structure (e.g., bottom critical dimension, middle critical dimension, top critical dimension, sidewall angle, grating height, etc.), a critical dimension between any two or more structures (e.g., distance between two structures), and a displacement between two or more structures (e.g., overlay displacement between overlaying grating structures, etc.). Structures may include three dimensional structures, patterned structures, overlay structures, etc.

As described herein, the term “critical dimension application” or “critical dimension measurement application” includes any critical dimension measurement.

As described herein, the term “metrology system” includes any system employed at least in part to characterize a specimen in any aspect, including critical dimension applications and overlay metrology applications. However, such terms of art do not limit the scope of the term “metrology system” as described herein. In addition, the metrology systems described herein may be configured for measurement of patterned wafers and/or unpatterned wafers. The metrology system may be configured as a LED inspection tool, edge inspection tool, backside inspection tool, macro-inspection tool, or multi-mode inspection tool (involving data from one or more platforms simultaneously), and any other metrology or inspection tool that benefits from the measurement techniques described herein.

Various embodiments are described herein for a semiconductor processing system (e.g., an inspection system or a lithography system) that may be used for processing a specimen. The term “specimen” is used herein to refer to a wafer, a reticle, or any other sample that may be processed (e.g., printed or inspected for defects) by means known in the art.

As used herein, the term “wafer” generally refers to substrates formed of a semiconductor or non-semiconductor material. Examples include, but are not limited to, monocrystalline silicon, gallium arsenide, and indium phosphide. Such substrates may be commonly found and/or processed in semiconductor fabrication facilities. In some cases, a wafer may include only the substrate (i.e., bare wafer). Alternatively, a wafer may include one or more layers of different materials formed upon a substrate. One or more layers formed on a wafer may be “patterned” or “unpatterned.” For example, a wafer may include a plurality of dies having repeatable pattern features.

A “reticle” may be a reticle at any stage of a reticle fabrication process, or a completed reticle that may or may not be released for use in a semiconductor fabrication facility. A reticle, or a “mask,” is generally defined as a substantially transparent substrate having substantially opaque regions formed thereon and configured in a pattern. The substrate may include, for example, a glass material such as amorphous SiO₂. A reticle may be disposed above a resist-covered wafer during an exposure step of a lithography process such that the pattern on the reticle may be transferred to the resist.

One or more layers formed on a wafer may be patterned or unpatterned. For example, a wafer may include a plurality of dies, each having repeatable pattern features. Formation and processing of such layers of material may ultimately result in completed devices. Many different types of devices may be formed on a wafer, and the term wafer as used herein is intended to encompass a wafer on which any type of device known in the art is being fabricated.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, XRF disc, digital versatile disc (DVD), floppy disk and blu-ray disc where disks usually reproduce data magnetically, while discs reproduce data optically with lasers. Combinations of the above should also be included within the scope of computer-readable media.

Although certain specific embodiments are described above for instructional purposes, the teachings of this patent document have general applicability and are not limited to the specific embodiments described above. Accordingly, various modifications, adaptations, and combinations of various features of the described embodiments can be practiced without departing from the scope of the invention as set forth in the claims.

What is claimed is:

1. A positioning system, comprising:
a first iron core linear motor assembly disposed adjacent to a first magnet assembly, wherein the first iron core linear motor assembly and the first magnet assembly are physically separated by a first magnetic gap, wherein a first magnetic attraction force is induced across the first magnetic gap, the first magnetic attraction force acting along a first axis; and
a second iron core linear motor assembly disposed adjacent to a second magnet assembly, wherein the second iron core linear motor assembly and the second magnet assembly are physically separated by a second magnetic gap, wherein a second magnetic attraction force is induced across the second magnetic gap, the second magnetic attraction force acting along the first axis in a direction opposite the first magnetic attraction force, wherein the first magnet assembly is mechanically coupled to the second magnet assembly and the first iron core linear motor assembly is mechanically coupled to the second iron core linear motor assembly.

2. The positioning system of claim 1, further comprising:
a base frame;
a first moving frame moveable with respect to the base frame along a second axis orthogonal to the first axis, wherein the first and second magnet assemblies are mechanically coupled to the first moving frame and the first and second iron core linear motor assemblies are mechanically coupled to the base frame.

3. The positioning system of claim 2, further comprising:
a second moving frame moveable with respect to the first moving frame along a third axis orthogonal to the second axis;
a third iron core linear motor assembly disposed adjacent to a third magnet assembly, wherein the third iron core linear motor assembly and the third magnet assembly are physically separated by a third magnetic gap, wherein a third magnetic attraction force is induced across the third magnetic gap, the third magnetic attraction force acting along a fourth axis orthogonal to the third axis; and
a fourth iron core linear motor assembly disposed adjacent to a fourth magnet assembly, wherein the fourth iron core linear motor assembly and the fourth magnet assembly are physically separated by a fourth magnetic gap, wherein a fourth magnetic attraction force is induced across the fourth magnetic gap, the fourth magnetic attraction force acting along the fourth axis in a direction opposite the third magnetic attraction force, wherein the third magnet assembly is mechanically coupled to the fourth magnet assembly and the third iron core linear motor assembly is mechanically coupled to the third linear motor assembly.

4. The positioning system of claim 3, wherein the third and fourth magnet assemblies are mechanically coupled to the first moving frame and the third and fourth iron core linear motor assemblies are mechanically coupled to the second moving frame.

5. The positioning system of claim 2, the first iron core linear motor assembly including a plurality of iron core linear motor units, the plurality of iron core linear motor units disposed adjacent to one another along a length of the first iron core linear motor assembly, each iron core linear motor unit including a plurality of electrically conductive coils, wherein a first of the plurality of electrically conductive coils of each of the plurality of iron core linear motor units are electrically coupled in series, and wherein a second of the plurality of electrically conductive coils of each of the plurality of iron core linear motor units are electrically coupled in series.

6. The positioning system of claim 1, further comprising:
a first cooling channel within a housing of the first iron core linear motor assembly; and
a second cooling channel within a housing of the second iron core linear motor assembly.

7. The positioning system of claim 6, wherein a cooling fluid or a cooling gas pass through the first and second cooling channels.

8. The positioning system of claim 1, wherein the first moving frame is constrained to move with respect to the base frame along the second axis by a mechanical bearing, an air bearing, or a magnetic bearing.

9. A measurement system, comprising:
an illumination source configured to generate an amount of illumination light directed to one or more structures fabricated on a semiconductor wafer;
a detector configured to detect an amount of light from the one or more structures in response to the amount of illumination light;
a wafer positioning system, comprising:
a first iron core linear motor assembly disposed adjacent to a first magnet assembly, wherein the first iron core linear motor assembly and the first magnet assembly are physically separated by a first magnetic gap, wherein a first magnetic attraction force is induced across the first magnetic gap, the first magnetic attraction force acting along a first axis; and
a second iron core linear motor assembly disposed adjacent to a second magnet assembly, wherein the second iron core linear motor assembly and the second magnet assembly are physically separated by a second magnetic gap, wherein a second magnetic attraction force is induced across the second magnetic gap, the second magnetic attraction force acting along the first axis in a direction opposite the first magnetic attraction force, wherein the first magnet assembly is mechanically coupled to the second magnet assembly and the first iron core linear motor assembly is mechanically coupled to the second iron core linear motor assembly; and
a computing system configured to determine a value of at least one parameter of interest characterizing the one or more structures under measurement based on the amount of detected light.

10. The measurement system of claim 9, the wafer positioning system, further comprising:
a base frame mechanically coupled to the illumination source and the detector;
a first moving frame moveable with respect to the base frame along a second axis orthogonal to the first axis, wherein the first and second magnet assemblies are mechanically coupled to the first moving frame and the first and second iron core linear motor assemblies are mechanically coupled to the base frame.

11. The measurement system of claim 10, the wafer positioning system, further comprising:
a second moving frame moveable with respect to the first moving frame along a third axis orthogonal to the second axis;
a third iron core linear motor assembly disposed adjacent to a third magnet assembly, wherein the third iron core linear motor assembly and the third magnet assembly are physically separated by a third magnetic gap, wherein a third magnetic attraction force is induced across the third magnetic gap, the third magnetic attraction force acting along a fourth axis orthogonal to the third axis; and
a fourth iron core linear motor assembly disposed adjacent to a fourth magnet assembly, wherein the fourth iron core linear motor assembly and the fourth magnet assembly are physically separated by a fourth magnetic gap, wherein a fourth magnetic attraction force is induced across the fourth magnetic gap, the fourth magnetic attraction force acting along the fourth axis in a direction opposite the third magnetic attraction force, wherein the third magnet assembly is mechanically coupled to the fourth magnet assembly and the third iron core linear motor assembly is mechanically coupled to the third linear motor assembly.

12. The measurement system of claim 11, wherein the third and fourth magnet assemblies are mechanically coupled to the first moving frame and the third and fourth iron core linear motor assemblies are mechanically coupled to the second moving frame.

13. The measurement system of claim 10, the first iron core linear motor assembly including a plurality of iron core linear motor units, the plurality of iron core linear motor units disposed adjacent to one another along a length of the first iron core linear motor assembly, each iron core linear motor unit including a plurality of electrically conductive coils, wherein a first of the plurality of electrically conductive coils of each of the plurality of iron core linear motor units are electrically coupled in series, and wherein a second of the plurality of electrically conductive coils of each of the plurality of iron core linear motor units are electrically coupled in series.

14. The measurement system of claim 9, the wafer positioning system, further comprising:
a first cooling channel within a housing of the first iron core linear motor assembly; and
a second cooling channel within a housing of the second iron core linear motor assembly.

15. The measurement system of claim 14, wherein a cooling fluid or a cooling gas pass through the first and second cooling channels.

16. The measurement system of claim 9, wherein the first moving frame is constrained to move with respect to the base frame along the second axis by a mechanical bearing, an air bearing, or a magnetic bearing.

17. A method comprising:
positioning a first moving frame moveable with respect to a base frame along a first axis, a first magnet assembly and a second magnet assembly mechanically coupled to the first moving frame and a first iron core linear motor assembly and a second iron core linear motor assembly mechanically coupled to the base frame, the first iron core linear motor assembly disposed adjacent to the first magnet assembly, wherein the first iron core linear motor assembly and the first magnet assembly are physically separated by a first magnetic gap, wherein a first magnetic attraction force is induced across the first magnetic gap, the first magnetic attraction force acting along a second axis, the second iron core linear motor assembly disposed adjacent to the second magnet assembly, wherein the second iron core linear motor assembly and the second magnet assembly are physically separated by a second magnetic gap, wherein a second magnetic attraction force is induced across the second magnetic gap, the second magnetic attraction force acting along the second axis in a direction opposite the first magnetic attraction force; and
positioning a second moving frame moveable with respect to the first moving frame along a third axis, wherein the third axis is orthogonal to the first axis, a third magnet assembly and a fourth magnet assembly mechanically coupled to the first moving frame and a third iron core linear motor assembly and a fourth iron core linear motor assembly mechanically coupled to the second moving frame, the third iron core linear motor assembly disposed adjacent to the third magnet assembly, wherein the third iron core linear motor assembly and the third magnet assembly are physically separated by a third magnetic gap, wherein a third magnetic attraction force is induced across the third magnetic gap, the third magnetic attraction force acting along a fourth axis, the fourth iron core linear motor assembly disposed adjacent to the fourth magnet assembly, wherein the fourth iron core linear motor assembly and the fourth magnet assembly are physically separated by a fourth magnetic gap, wherein a fourth magnetic attraction force is induced across the fourth magnetic gap, the fourth magnetic attraction force acting along the fourth axis in a direction opposite the third magnetic attraction force.

18. The method of claim 17, wherein a semiconductor wafer chuck is disposed above the second moving frame, and wherein an illumination source and detector of a semiconductor measurement system are mechanically coupled to the base frame.

19. The method of claim 17, further comprising:
flowing a first amount of cooling fluid or cooling gas through a first cooling channel within a housing of the first iron core linear motor assembly; and
flowing a second amount of cooling fluid or cooling gas through a second cooling channel within a housing of the second iron core linear motor assembly.

20. The method of claim 17, further comprising:
constraining the first moving frame is constrained to move with respect to the base frame along the first axis by a mechanical bearing, an air bearing, or a magnetic bearing.
